(19) United States
(12) Patent Application Publication
(10) Pub. No.: US 2026/0009873 A1
(43) Pub. Date: Jan. 8, 2026

(54) CONDUCTING LOOP WITH INDUCTIVE PATH FOR MAGNETIC RESONANCE IMAGING (MRI) RECEIVE COIL

(71) Applicant: KONINKLIJKE PHILIPS N.V., EINDHOVEN (NL)

(72) Inventors: Zhiyong Zhai, Gainesville, FL (US); Paul Royston Harvey, Best (NL); Cecilia Possanzini, Best (NL); Daniel Trabbic, Rocky River, OH (US); Scott Bradley King, Gainesville, FL (US)

(21) Appl. No.: 18/993,592

(22) PCT Filed: Jul. 10, 2023
(86) PCT No.: PCT/EP2023/068995

§ 371 Date: Jan. 13, 2025

Related U.S. Application Data
(60) Provisional application No. 63/388,673, filed on Jul. 13, 2022.

(51) Int. Cl. G01R 33/36; G01R 33/3415

(52) U.S. Cl. CPC G01R 33/3628; G01R 33/3415

(57) ABSTRACT

A magnetic resonance (MR) receive coil (18) includes a conducting loop (20) that is resonant at a Larmor frequency of a design-basis B₀ magnetic field of at least 3 Tesla; and a conducting trace (22) configured to detune the conducting loop from the Larmor frequency in response to a DC current flowing through the conducting trace. The conducting trace further includes a receive |B₁|-field uniformity-enhancing inductor (L3) positioned at an intermediate point along the conducting trace.

### FIELD

The following relates generally to the magnetic resonance (MR) imaging arts, MR coil arts, high magnetic field MR signal acquisition arts, MR detuning arts, and related arts.

### BACKGROUND

Magnetic resonance (MR) imaging entails placing a subject (e.g., medical patient, veterinary subject, archaeological mummy, et cetera) in a static magnetic field (often referred to as a B₀ field) and exciting nuclear magnetic resonance in the subject and then detecting the excited magnetic resonance. For imaging, the excited MR is spatially encoded with respect to location, phase, and/or frequency by superimposing magnetic field gradients on the static B₀ magnetic field during the excitation, during a time interval between MR excitation and MR readout, and/or during the MR readout. In a typical design, the MR imaging device (sometimes referred to as an MRI scanner) includes a housing with a central bore within which the MR examination region is located. The static B₀ magnetic field is produced by solenoidal magnet windings wrapped around the central bore and housed within the MRI scanner housing. These solenoidal magnet windings are often superconducting windings in modern MRI scanners, and the housing includes a liquid helium (LHe) reservoir cooling the superconducting windings. Magnetic field gradient coils are also disposed in the housing around the central bore.

To provide the MR excitation in the case of a human subject, a body coil is commonly used, which is typically a cylindrical birdcage coil, TEM coil, or some variant thereof that is installed concentrically around the bore. Alternatively, a local coil positioned near the body anatomy to be imaged is used for excitation. MR readout is usually performed using a local MR receive coil positioned near the anatomy to be imaged. The local MR receive coil and the local MR excitation coil readout (if used) may be the same coil, or different coils. For various reasons, the MR receive coil (and MR excitation coil, if used) may comprise an MR coil that includes one or more coil elements, with each coil element typically configured as a loop coil, although other coil element designs are known.

In present coil designs, a single loop is used in a design-basis Bo magnetic field of at least 3 Tesla. However, such single loops used in B₀ magnetic fields of 3 T and above suffer from a receive |B₁|-field distortion, resulting in a reduced MRI signal to noise ratio (SNR).

The following discloses certain improvements to overcome these problems and others.

### SUMMARY

In some embodiments disclosed herein, a magnetic resonance (MR) receive coil includes a conducting loop that is resonant at a Larmor frequency of a design-basis B₀ magnetic field of at least 3 Tesla; and a conducting trace configured to detune the conducting loop from the Larmor frequency in response to a DC current flowing through the conducting trace. The conducting trace further includes a receive |B₁|-field uniformity-enhancing inductor positioned at an intermediate point along the conducting trace.

In some embodiments disclosed herein, a method of optimizing receive |B₁|-field uniformity of a MR receive coil includes placing the MR receive coil in a design-basis B₀ magnetic field of at least 3 Tesla with the MR receive coil coupled with a dielectric body. The MR receive coil includes a conducting loop that is resonant at a Larmor frequency of design-basis B₀ magnetic field, and a conducting trace configured to detune the conducting loop from the Larmor frequency in response to a DC current flowing through the conducting trace, the conducting trace further including a receive |B₁|-field uniformity-enhancing inductor positioned on a portion of the conductive trace oriented parallel with the design-basis Bo magnetic field. The method further includes adjusting one or more components of the MR receive coil including at least the receive |B₁|-field uniformity-enhancing inductor to optimize receive |B₁|-field uniformity of the MR receive coil placed in the design-basis B₀ magnetic field and coupled with the dielectric body.

One advantage resides in providing an MRI receive coil with a reduced receive |B₁|-field distortion.

Another advantage resides in providing an MRI receive coil with a conducting trace positioned on one side of a single loop coil.

Another advantage resides in increasing a SNR of an MR scanner.

Another advantage resides in providing an MRI receive coil with a conducting trace including a receive |B₁|-field uniformity-enhancing inductor positioned on a portion of the conductive trace oriented parallel with the design-basis B₀ magnetic field.

A given embodiment may provide none, one, two, more, or all of the foregoing advantages, and/or may provide other advantages as will become apparent to one of ordinary skill in the art upon reading and understanding the present disclosure.

### BRIEF DESCRIPTION OF THE DRAWINGS

The disclosure may take form in various components and arrangements of components, and in various steps and arrangements of steps. The drawings are only for purposes of illustrating the preferred embodiments and are not to be construed as limiting the disclosure.

FIG. 1 diagrammatically illustrates a magnetic resonance (MR) imaging device including a MR coil element in accordance with the present disclosure.

FIG. 2 shows the MR coil for the device of FIG. 1.

FIGS. 3-5 show experimental data for the MR coil of FIG. 2.

FIG. 6 diagrammatically illustrates an MRI imaging method using the device of FIG. 1.

### DETAILED DESCRIPTION

At high B₀ magnetic fields, such as 3 T and above, |B₁|-field distortion becomes an issue due to the short radio frequency (RF) wavelength inside a patient. For example, at 3 T the magnetic resonance (MR) resonant frequency is at 128 MHz corresponding to RF wavelength of 2.34 meters in air. The wavelength is shortened inside the patient to a length comparable to the cross-sectional diameter of the patient due to the dielectric effect. The shortened wavelength causes the constructive and destructive interference of |B₁|-field inside the patient which distorts the |B₁|-field.

The following discloses using a conductive copper trace, which is sometimes included in an MR receive coil for performing detuning of the MR receive coil loop during the transmit phase, to also suppress the receive |B₁|-field distortion so as to enhance receive |B₁|-field uniformity. In some embodiments, an additional inductor is included in the copper trace, positioned in some embodiments at a symmetric position along the z-direction (which is the direction of the B₀ field). The MR receive coil may sometimes further include end inductors L1 and L2 for the pass-through of DC for performing detuning of the MR receive coil loop during the transmit phase.

In addition to providing the additional, e.g. symmetrically centered, inductor for suppressing the receive |B₁|-field distortion, the following discloses a method of calibrating the coil loop to enhance the receive |B₁|-field uniformity. In one approach, the inductors of the MR receive coil (excepting the inductor added for suppressing receive |B₁|-field distortion) have fixed inductance values (e.g. 1.8 microHenries in one nonlimiting illustrative example), and the calibration method includes adjusting the inductance of the added inductor to optimize receive |B₁|-field uniformity. A phantom representing the patient dielectric mass can be used in the calibration method, or electromagnetic simulation of the coil and the dielectric mass could alternatively be used. The disclosed calibration approach in some embodiments entails adjusting a center inductor which is symmetrically positioned on the coil loop along the z-direction. The optimization is an empirical process.

The calibration of the coil loop to optimize receive |B₁|-field uniformity is typically performed once, at the factory where the MR receive coil is manufactured. The calibrated coil loop may then be installed as one coil loop of an MR coil comprising an array of such coil loops. When the MR coil is used for patient imaging, the calibrated MR coil loop should be positioned in the same spatial orientation respective to the Bo field and patient as was used in the calibration. In practice, the calibrated coil loop is typically part of a coil array that is sized and shaped to couple with a particular part of the human anatomy (e.g., a head coil array or a torso coil array) and so the proper positioning of the coil loop in clinical use is naturally achieved.

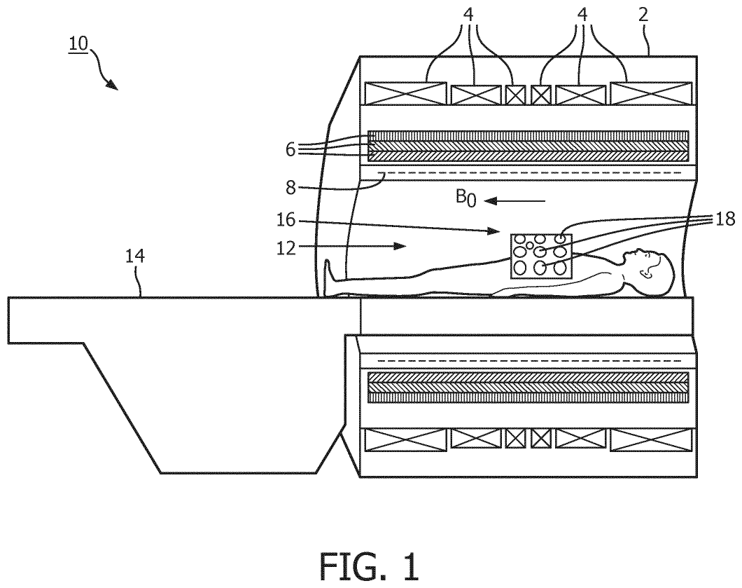

With reference to FIG. 1, an illustrative magnetic resonance (MR) imaging system or device 10 comprises a magnetic resonance (MR) imaging scanner, such as a MR scanner generating a magnetic field of at least 3 Tesla (3 T). As shown in FIG. 1, the MR device 10 includes a housing or gantry 2 containing various components shown in FIG. 1, such as by way of non-limiting illustrative example a superconducting magnet 4 generating a static (B₀) magnetic field as diagrammatically indicated in FIG. 1, magnetic field gradient coils 6 for superimposing magnetic field gradients on the B₀ magnetic field, a whole-body radio frequency (RF) coil 8 for applying RF pulses to excite and/or spatially encode magnetic resonance in an imaging patient disposed in an MR bore 12 or other MR examination region, and/or so forth. The magnet 4 and the gradient coils 6 are arranged concentrically about the bore 12. A robotic patient couch 14 or other patient support enables loading a medical patient, a patient undergoing a medical screening, or other imaging patient into the MR bore 12 for imaging. The magnetic resonance excited in the imaging subject is read out by an MR receive coil 18. FIG. 1 shows an illustrative MR coil 16 is an array of coil loops 18, i.e. MR receive coils 18. It will be appreciated that the coil array 16 may in general include any number of coil elements, e.g., 16 coil elements, 20 coil elements, 32 coil elements, etc. In some examples, MR coil 16 is configured to be disposed in the examination region (i.e., the MR bore 12), as shown in FIG. 1.

Typically, the MR coil 16 will be disposed in a fixed orientation relative to the B₀ magnetic field generated by the magnet 4. For example, the illustrative coil 16 is a torso coil that is laid on the torso of the patient in a fixed orientation. Consequently, each MR receive coil 18 making up the coil array 16 is also typically positioned on the patient in a fixed spatial orientation respective to the Bo magnetic field. It will also be noted that the MR coil array 16 (and hence its constituent MR receive coil loops 18) are placed on or in close proximity to the patient. This advantageously provides strong electromagnetic coupling between the patient and the MR receive coil loops 18. However, at high magnetic field, such as |B₀|=3 Tesla or higher in some embodiments, |B₁|-field distortion can occur due to the dielectric effect of the patient. As previously noted, this is a consequence of the shortened wavelength inside the patient at high field becoming comparable with the cross-sectional diameter of the patient.

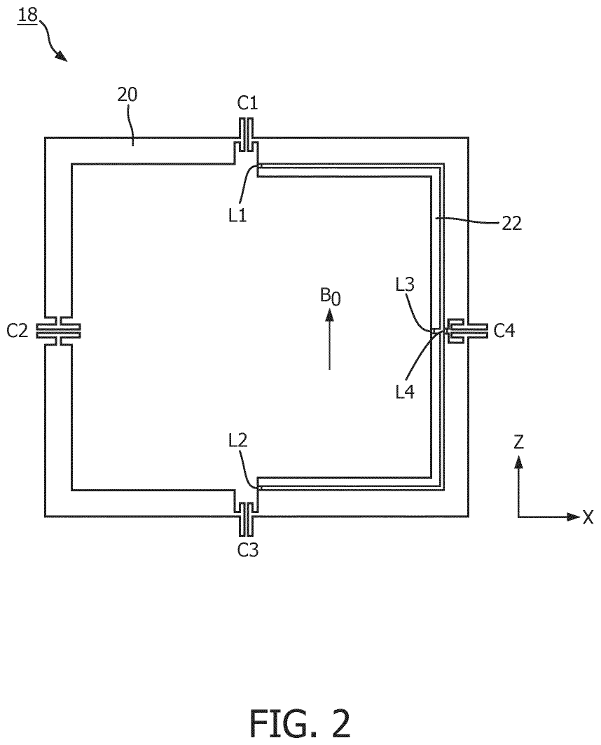

Referring now to FIG. 2, one illustrative MR receive coil 18 of the MR coil (array) 16 of FIG. 1 is shown. The MR receive coil 18 comprises, for example, a conducting loop 20 that is resonant at a Larmor frequency of a design-basis B₀ magnetic field of at least 3 T. The illustrative conducting loop 20 is a single loop of copper, copper alloy, or another electrically conductive material, for example formed as a copper layer deposited on a circuit board, plastic sheet, plastic former, or other electrically insulating substrate; or alternatively formed as a freestanding metal loop. The conducting loop 20 includes at least one capacitor (four of which, labeled C1-C4, are shown in FIG. 2), and in the illustrative example further includes an inductor (labelled in FIG. 2 as L4) placed in parallel across the capacitor C4 to form an LC detuning circuit for detuning MR receive coil 18 during the whole-body coil 8 transmit phase. The illustrative conducting loop 20 is rectangular, but other geometries are contemplated, e.g. circular or so forth. Note that the copper layer or the like making up the bulk of the conducting loop 20 may have gaps at the locations of the capacitors C1-C4, so that connection of the capacitors across these gaps collectively forms the conductive loop 20. It is to be further appreciated that the conducting loop 20 is electrically conductive (and resonant) at the Larmor frequency; however, at DC the conducting loop 20 may be electrically nonconductive due to the presence of the capacitors C1-C4 which act as blocking capacitors to block DC electric current flow around the conducting loop 20.

The MR coil 18 also includes a conducting trace 22, which is separate from the conducting loop 20 and lies alongside it in sufficiently close proximity to enable inductive coupling between the conducting loop 20 and the conducting trace 22 at (and near) the Larmor frequency. The conducting trace 22 is configured to detune the conducting loop 20 from the Larmor frequency in response to a DC current flowing through the conducting trace 22. As shown in FIG. 2, the conducting trace 22 runs parallel with the conducting loop 20 along a portion of the conducting loop 20. In the illustrative example, the conducting trace 22 runs parallel with the conducting loop 20 along one-half of the conducting loop 20, although deviations from this one-half fraction are contemplated.

The conducting trace 22 includes a plurality of inductors (labeled in FIG. 2 as L1-L3). Multiple (illustrative two) of the inductors (for example, L1 and L2) can be coupling inductors connecting opposite ends of the conducting trace 22 to the conducting loop 20. At least one of the inductors (illustrative inductor L3) comprises a receive | B1|-field uniformity-enhancing inductor. The receive |B₁|-field uniformity-enhancing inductor L3 is tuned to optimize receive |B₁|-field uniformity of the MR receive coil 18 when the MR receive coil 18 is placed in the design-basis B₀ magnetic field with a leg of the conducting trace 20 containing the receive |B₁|-field uniformity-enhancing inductor oriented parallel with the design-basis B₀ magnetic field. In the illustrative example of FIG. 2, the MR receive coil loop 18 is positioned in the overall coil array 16 (see FIG. 1) with the B₀ magnetic field oriented parallel to the leg of the conducting trace 20 that includes the inductor L3 in this illustrative example. For the illustrative X-Z coordinate system shown in FIG. 2, this corresponds to the B₀ magnetic field being oriented in the Z-direction and likewise the leg of the MR receive coil loop 18 that includes the receive |B₁|-field uniformity-enhancing inductor L3 also being oriented along the Z-direction parallel with the B₀ magnetic field.

The receive |B₁|-field uniformity-enhancing inductor L3 is positioned at an intermediate point along the conducting trace 22. In one example, the B1-field uniformity-enhancing inductor L3 is positioned at a midpoint of the conducting loop 20. In another example, the B1-field uniformity-enhancing inductor L3 is located with one of the capacitors of the conducting loop 20 (i.e., capacitor C4 as shown in FIG. 2).

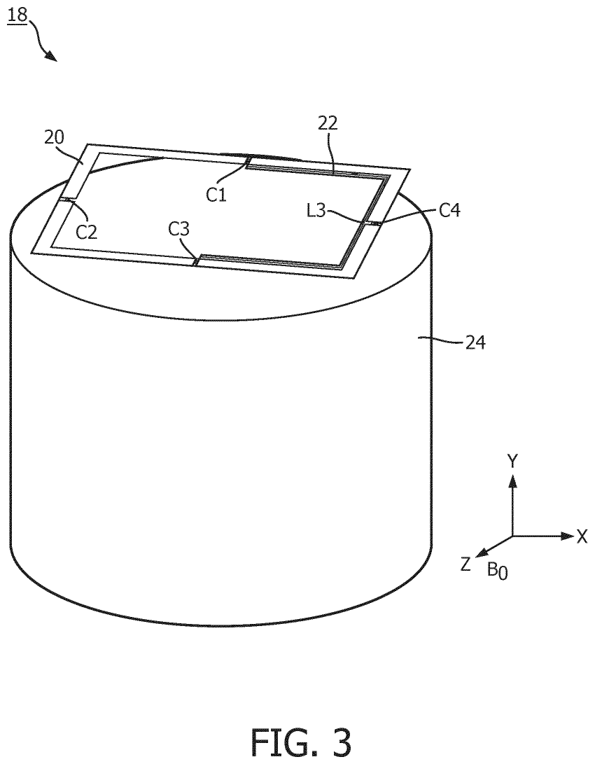

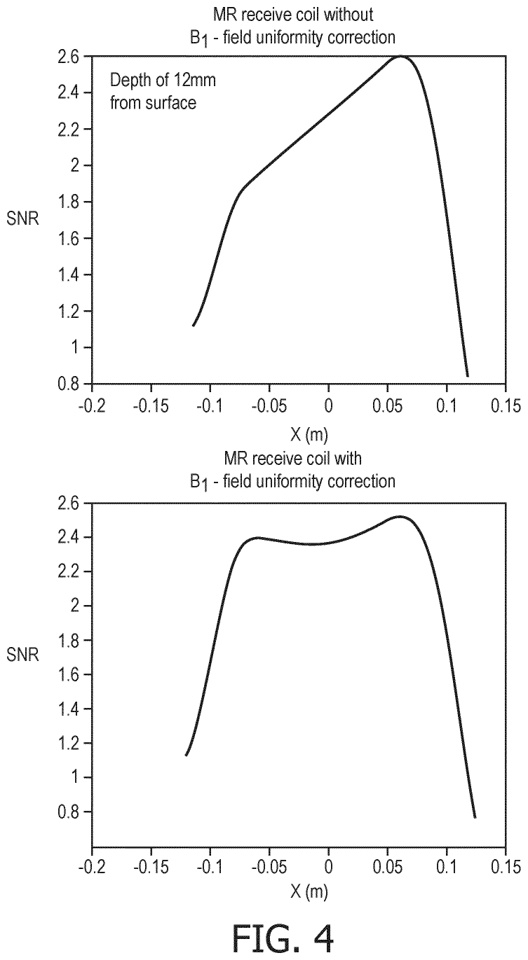

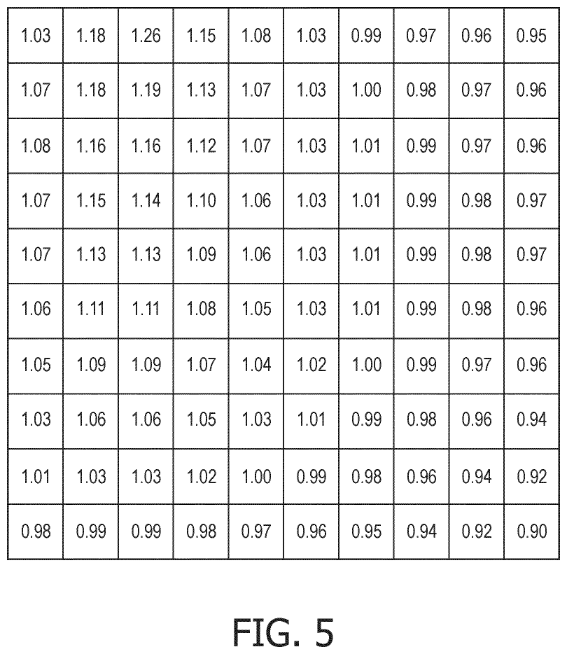

FIGS. 3-5 show example experimental data of the MR coil 18. FIG. 3 shows a simulation setup of the MR coil 18 including the single conducting loop 20 with the conducting trace 22 on the left half side of the loop 20, disposed on a simulated dielectric body or mass 24 that simulates the effect of the patient. The simulated coil 18 is oriented with the leg containing the capacitor C4 next to the receive |B₁|-field uniformity-enhancing inductor L3 oriented parallel with the B₀ field (along the Z-direction using the illustrative X-Y-Z coordinate system). The loop 20 that is simulated in the examples of FIGS. 4 and 5 has the size of 92 mm along z-axis (main magnet B₀-direction) and 112 mm along x-axis (patient left-right direction). The loop 20 conducting width is 6 mm and the trace 22 conducting width is 2 mm. In this embodiment, the conducting trace 22 is placed inside the loop 20 alongside the leg containing the capacitor C4, with the conducting trace 22 positioned 2 mm away from the loop 20. In another embodiment, the trace 22 can be placed under or above the single loop conductor 20. To reduce the footprint of the extra trace 22 in practice, the conducting width of the trace 22 can be smaller than the loop 20. Furthermore, the trace 22 can share with part of the single loop conductor 20 to form a closed DC path for detuning the single loop 20 during the whole-body coil 8 transmit phase. In one embodiment, the trace 22 can be part of a DC path. In another embodiment, the trace 22 can be a stand along conducting trace. A DC voltage source (not shown) is suitably placed in the L4 location since L4 value has the least sensitivity to the correction of the receive |B₁|-field distortion.

To calibrate the MR receive coil 18 using this simulation (or, alternatively, using a physical setup such as a physical instance of the coil 18 and a physical body 24 made of a biological or synthetic material whose dielectric properties approximate those of a patient), the single loop 20 is tuned to 128 MHz resonance (MRI at 3 T, or more generally tuned to the Larmor frequency of the design-basis B₀ magnetic field strength) with four capacitors C1-C4 of 18 pF (in this specific example). Next, four inductors L1-L4 are placed along the DC path: L1 (1.8 μH) and L2 (1.8 μH) are at two ends of trace 22, and L4 (1.8 μH) is placed parallel to C4 in the single loop 20. The inductor L3 is at middle-point of trace 22 then tuned to optimally suppress the receive |B₁|-field distortion. In the specific example, a value of inductance for the inductor L3 of 1.69 μH was found to be suitable for this purpose.

In operation, during the whole-body coil 8 transmit phase, the trace 22 and the four inductors L1-L4 provide a closed DC path to control the bias diode for single loop 20 detuning. During the receive coil 18 receive phase, the DC path functions as an extra conducting trace for providing receive |B₁|-field uniformity correction. In practice, a resistor R is optionally used in the DC path to regulate bias DC current. The resistance of the resistor R can be adjusted for both optimal receive |B₁|-field uniformity correction and satisfaction of DC bias current. In this example, R is chosen at value of 40 Ω and located in the conducting trace 22 next to inductor L3, although the resistor R could be placed elsewhere in the conducting trace 22.

To demonstrate the advantageous suppression of receive |Bi|-field distortion provided by the disclosed MR coil 18 with the receive |B₁|-field uniformity-enhancing inductor L3 thusly tuned, a conventional single loop coil is modelled without the extra conducting trace using the same simulation setup of FIG. 3. The conventional loop is also tuned to the same resonance of 128 MHz with the same four capacitors of 18 pF. Both MR receive coil loop designs are simulated with a placement 10 mm-above a 150 mm-diameter cylindrical uniform phantom 24 simulating the dielectric properties of the patient by having conductivity of 0.6 S/m and relative permittivity of 78, respectively. The phantom 24 has the length of 120 cm along the Y-direction indicated in FIG. 3. A radio frequency (RF) voltage source V (not shown) is placed parallel to capacitor C3, and the simulated signal-to-noise ratio (SNR) is calculated over the center transverse slice of the phantom 24 for comparison.

FIG. 4 shows a calculated SNR for the conventional single loop (without the receive |B₁|-field uniformity correction disclosed herein; upper plot) and the disclosed MR coil 18 including the loop 20 and the conducting trace 22 with the receive |B₁|-field uniformity-enhancing inductor L3 tuned to 1.69 μH as described previously (lower plot). A SNR line along the x-axis in the depth of y=12 mm from the surface of phantom is plotted in FIG. 4. As seen, the MR coil 18 with receive |B₁|-field uniformity correction (lower plot) has improved left-right SNR uniformity compared with the conventional loop (upper plot).

FIG. 5 shows a table of SNR ratio values of the MR coil 18 to a conventional loop coil over the center transverse slice (Z=0 plane) of phantom 24, which show SNR improvement (>1) over most areas. Each box represents a spatial location in the X-Y plane, and the value labelling that box is the ratio of the SNR of the MR coil 18 with receive |B₁|-field uniformity correction to the SNR of the MR coil 18 without receive |B₁|-field uniformity correction. Of note are the boldfaced SNR values highlighting where the B₁-field uniformity correction has improved the SNR uniformity.

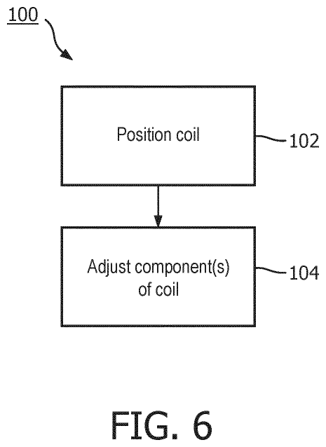

With reference to FIG. 6, and with continuing reference to FIGS. 1 and 2, an illustrative method 100 of optimizing receive |B₁|-field uniformity of the MR coil 18 is diagrammatically shown as a flowchart. To begin the method 100, at an operation 102 the MR receive coil 18 to be tuned is placed in an MR scanner or other source of the design-basis B₀ magnetic field, with the coil 18 placed on the dielectric phantom 24 (see FIG. 3) and oriented respective to that B0 magnetic field as it will be in the coil array 16 (see FIG. 1). At the operation 102, the MR coil 18 is placed onto the phantom 24 so that the MR coil 18 is placed in in a design-basis B0 magnetic field of at least 3 Tesla with the MR receive coil 18 coupled with a dielectric body 24 (i.e., the phantom). At an operation 104, one or more components of the MR receive coil 18 are adjusted. For example, at least the receive |B₁|-field uniformity-enhancing inductor L3 is adjusted to optimize receive |B₁|-field uniformity of the MR receive coil 18 placed in the design-basis B₀ magnetic field and coupled with the dielectric body. For another example, a resistor R in trace 22 is adjusted to both optimize receive |B₁|-field uniformity of MR receive coil 18 and to satisfy of DC bias current for MR receive coil 18 detuning. The impedance of the additional inductors L1, L2 can be fixed. The adjusting operation 104 can be performed on a phantom or by an electromagnetic simulation.

The disclosure has been described with reference to the preferred embodiments. Modifications and alterations may occur to others upon reading and understanding the preceding detailed description. It is intended that the exemplary embodiment be construed as including all such modifications and alterations insofar as they come within the scope of the appended claims or the equivalents thereof.

1. A magnetic resonance (MR) receive coil, comprising:
a conducting loop that is resonant at a Larmor frequency of a design-basis B₀ magnetic field of at least 3 Tesla; and
a conducting trace configured to detune the conducting loop from the Larmor frequency in response to a DC current flowing through the conducting trace, the conducting trace further including a receive |B₁|-field uniformity-enhancing inductor positioned at an intermediate point along the conducting trace.

2. The MR receive coil of claim 1, wherein the receive |B₁|-field uniformity-enhancing inductor is tuned to optimize receive |B₁|-field uniformity of the MR receive coil when the MR receive coil is placed in the design-basis B₀ magnetic field with a leg of the conducting trace containing the receive |B₁| field uniformity-enhancing inductor oriented parallel with the design-basis B₀ magnetic field.

3. The MR receive coil of claim 1, wherein the receive |B₁|-field uniformity-enhancing inductor is positioned at a midpoint of the conducting loop.

4. The MR receive coil of claim 1, wherein the conducting trace runs parallel with the conducting loop along a portion of the conducting loop.

5. The MR receive coil of claim 1, wherein the conducting trace runs parallel with the conducting loop along one-half of the conducting loop.

6. The MR receive coil of claim 1, wherein the conducting trace includes at least two additional inductors in addition to the receive |B₁|-field uniformity-enhancing inductor.

7. The MR receive coil of claim 1, wherein the at least two additional inductors include:
two coupling inductors connecting opposite ends of the conducting trace to the conducting loop.

8. The MR coil of claim 1, wherein the conducting loop comprises at least one capacitor.

9. The MR coil of claim 8, wherein the at least one capacitor includes a capacitor of the conducting loop located with the receive |B₁|-field uniformity-enhancing inductor.

10. A method of optimizing receive |B₁|-field uniformity of a magnetic resonance (MR) receive coil, the method comprising:
placing the MR receive coil in a design-basis B₀ magnetic field of at least 3 Tesla with the MR receive coil coupled with a dielectric body, the MR receive coil including:
a conducting loop that is resonant at a Larmor frequency of design-basis B₀ magnetic field, and
a conducting trace configured to detune the conducting loop from the Larmor frequency in response to a DC current flowing through the conducting trace, the conducting trace further including a receive |B₁|-field uniformity-enhancing inductor positioned on a portion of the conductive trace oriented parallel with the design-basis B₀ magnetic field; and
adjusting one or more components of the MR receive coil including at least the receive |B₁|-field uniformity-enhancing inductor to optimize receive |B₁|-field uniformity of the MR receive coil placed in the design-basis B₀ magnetic field and coupled with the dielectric body.

11. The method of claim 10, further including:
adjust an impedance of the receive |B₁|-field uniformity-enhancing inductor while fixing an impedance of additional inductors of the conducting trace.

12. The method of claim 10, wherein adjusting is performed on a phantom or by an electromagnetic simulation.

13. The method claim 10, further including:
tuning the receive |B₁|-field uniformity-enhancing inductor to optimize receive |B₁|-field uniformity of the MR receive coil when the MR receive coil is placed in the design-basis B₀ magnetic field with a leg of the conducting trace containing the receive |B₁|-field uniformity-enhancing inductor oriented parallel with the design-basis B₀ magnetic field.

14. The method of claim 10, further including:
positioning the receive |B₁|-field uniformity-enhancing inductor at a midpoint of the conducting loop.

15. The method of claim 10, further including:
positioning the conducting trace to run parallel with the conducting loop along a portion of the conducting loop.

16. The method of claim 10, further including:
positioning the conducting trace to run parallel with the conducting loop along one-half of the conducting loop.

17. The method of claim 10, wherein the conducting trace includes at least two additional inductors in addition to the receive |B₁|-field uniformity-enhancing inductor.

18. The method of claim 10, wherein the at least two additional inductors include:
two coupling inductors connecting opposite ends of the conducting trace to the conducting loop.

19. The method of claim 10, wherein the conducting loop comprises at least one capacitor.

20. The method of claim 19, wherein the at least one capacitor includes a capacitor of the conducting loop located with the receive |B₁|-field uniformity-enhancing inductor.
